(19) United States
(12) Patent Application Publication
(10) Pub. No.: US 2024/0304587 A1
(43) Pub. Date: Sep. 12, 2024

(54) POWER MODULE, ELECTRICAL DEVICE AND METHOD FOR PRODUCING A POWER MODULE

(71) Applicant: SIEMENS AKTIENGESELLSCHAFT, München (DE)

(72) Inventors: Claus Florian Wagner, Nürnberg (DE); Thomas Bigl, Herzogenaurach (DE); Stefan Pfefferlein, Heroldsberg (DE)

(21) Appl. No.: 18/277,443

(22) PCT Filed: Dec. 10, 2021
(86) PCT No.: PCT/EP2021/085263

§ 371 Date: Aug. 16, 2023

(30) Foreign Application Priority Data
Feb. 18, 2021 (EP) 21157873.7

(51) Int. Cl. H01L 23/00

(52) U.S. Cl. CPC H01L 24/32; H01L 24/83; H01L 2224/32225; H01L 2224/8384

(57) ABSTRACT

The invention relates to a power module (1) comprising a substrate (2). an electrically conductive intermediate layer (3) which is arranged on the substrate (2) and which has a joining region (4) produced by means of sintering, and at least one power component (5) which is arranged on the intermediate layer (3) and the sintered joining region (4) and is connected thereto (in particular at the load connection of the power component (5)) and which has at least one connection point (6) (e.g. a control connection) connected to the intermediate layer (3), wherein the intermediate layer (3) has. in the region of the associated connection point (6). a solder region (7) produced by means of a solder preform and spaced and/or electrically insulated from the sintered joining region (4). The large active surface, which is subjected to high thermomechanical stress in the service life test. can therefore be connected via the sintered joining region (4), which ensures an especially long-lasting, reliable and resilient mechanical connection between the associated power component (5) and the substrate (2). At the associated connection point (6), e.g. the gate of a transistor, the thermomechanical stress is usually much less, which is why there in the intermediate layer (3) a solder preform can be used for producing the connection between the associated power component (5) and the substrate (2), such solder preforms being relatively cost-effectively obtainable. Furthermore. an electrical device (10) has at least one such power module (1). The joining region (4) produced by means of sintering can be formed by means of a sinter preform or by means of 3D printing. by means of a coating method or by means of screen printing/stencil printing. In the method for producing the power module (1). the intermediate layer (3) can be heated to the melting temperature of the solder if the melting temperature of the solder is higher than the sintering temperature or to the sintering temperature if the sintering temperature is higher than the melting temperature of the solder, and the layer thickness (9) of the sintering material for the joining region (4) produced by means of sintering can be larger or smaller than the layer thickness (9) of the solder for the associated solder region (7) if the sintering temperature is correspondingly lower or higher than the melting temperature of the solder. Alternatively. the melting temperature of the solder can be substantially the same as the sintering temperature, and the layer thickness (9) of the sintering material for the joining region (4) produced by means of sintering can be substantially the same as the layer thickness (9) of the solder for the associated solder region (7). The sintered joining region (4) can have a sintering core (4″) which is in the form of solid material and which has. on each of its two sides. i.e. facing the power component (5) and facing the substrate (2), a sintering material (4′): also envisageable would be a layered. sintered joining region (4) in which sintering material and solid material alternate layer-by-layer. i.e. sintering material-solid material-sintering material-solid material-sintering material.

### CROSS REFERENCE TO RELATED APPLICATIONS

This present patent document is a § 371 nationalization of PCT Application Serial Number PCT/EP2021/085263, filed Dec. 10, 2021, designating the United States which is hereby incorporated in its entirety by reference. This patent document also claims the benefit of EP21157873.7 filed on Feb. 18, 2021, which is hereby incorporated in its entirety by reference.

### FIELD

Embodiments relate to a power module, an electrical device, and a method for producing the power module.

### BACKGROUND

Sintering technology is increasingly being relied upon in order to improve the life in the case of high-power semiconductors when connecting the chip to the DCB (direct bonded copper) substrate. The sintering deposits are conventionally produced in screen printing using sintering paste. It is difficult, for example with small connection faces, such as a gate connection of a power semiconductor, to produce deposits having a wet film thickness of more than 120 μm. This has an impact primarily when very large and very small deposits have to be produced in one operation or close together. Typical problems are irregular film thicknesses, the paste escaping from the apertures, excess paste at the end of the aperture (earing or what is known as “doggy ears”), air pockets and poor release behavior of the paste from the aperture.

In the case of printing sintering paste, there previously has not been a solution to the problems stated above, and this may result in a limited technical feasibility and/or in losses in reliability. Alternatively, for larger faces, for example larger than 1.6 mm×1.6mm, sintering preforms are used, but owing to the porous sintering paste on the upper and lower sides thereof these cannot be produced or punched as small as desired. Furthermore, sintering preforms are usually cost-intensive and often only available from a single supplier as a single source.

### BRIEF DESCRIPTION AND SUMMARY

The scope of the embodiments is defined solely by the appended claims and is not affected to any degree by the statements within this summary. The present embodiments may obviate one or more of the drawbacks or limitations in the related art.

Embodiments provide an improved power module, a corresponding electrical device, and a corresponding method. A power module may be provided where the intermediate layer, in the region of the respective connection point, includes a solder region produced by a solder preform, that is connected to the respective connection point.

An electrical device is also provided where the electrical device includes at least one such power module. A method is also provided for producing the power module by way of the following steps: providing the substrate, arranging the sinter material for the joining region to be sintered and the solder for the respective solder region on the substrate to form the intermediate layer, wherein the solder for the respective solder region is provided as a solder preform in the region of the respective connection point of the respective power component, arranging the respective power component on the joining region and the respective solder region or on the intermediate layer, and heating the intermediate layer to the melting temperature of the solder or to the sintering temperature.

The power module includes a substrate on which an electrically conductive intermediate layer is arranged. This intermediate layer includes a joining region. The intermediate layer is produced by sintering. Sintering, as is known, is a method for producing or changing materials. Fine-grained ceramic or metallic substances are heated—often under elevated pressure—although the temperatures remain below the melting temperature of the main components. Arranged on the intermediate layer is a power component, that includes at least one connection point, for example in order to supply the power component with an electrical voltage or an electrical current via the respective connection point. The respective connection point is connected, for example electrically connected, to the intermediate layer.

By way of example, the sintered joining region may include a sintering core configured as a solid material, which on both sides, in other words, facing the power component and facing the substrate, includes one sintering material respectively. In addition, a layered, sintered joining region may be used in which sintering material and solid material alternate in layers, for example sintering material-solid material-sintering material-solid material-sintering material.

The intermediate layer also includes, in the region of the respective connection point, a solder region, that is connected, for example is electrically connected, to the respective connection point. The respective solder region includes solder, for example a connecting material, that connects metals by way of soldering. The solder is made, for example, from a mixture or alloy of different metals. Lead, tin, zinc, silver, antimony, and copper may be used. The respective solder region is produced by a solder preform. A solder preform is, for example, a solder preform or a solder molded part, for example a cuboid, cylinder, ring, or the like in a desired size, for example made from solder alloys. Such solder preforms may be supplied, for example on belts or in trays, in varied dimensions and may be processed analogously to SMD (“Surface Mount Devices”) resistors or capacitors.

A semiconductor component or power semiconductor, for example, may be used as a power component, for example components that are based, for example, on silicon, gallium nitride or silicon carbide, and that are configured in power electronics for controlling and switching high electrical currents and voltages, for example currents of more than 1 ampere and voltages of more than approximately 24 volts. Examples of such components are power diodes, thyristors, triacs and transistors, such as power MOSFETs, IGBTs and the like. Furthermore, an electrical resistor, for example a measuring resistor, may be used as the power component.

Power components of this kind are often comparatively thin components, for example the dimensions of the base area are significantly larger than the thickness of the respective power component perpendicular to the base area. For example, power components of this kind have a substantially flat upper or lower side, for example since they are substantially cuboidal or cylindrical. For example, one side of the power component rests on the intermediate layer.

The intermediate layer includes the joining region produced by sintering (hereinafter also “sintered joining region”) and the respective solder region. Just like typical power components the intermediate layer also conventionally has the form of a flat cube or cylinder, for example with a—compared to the thickness of the intermediate layer—large upper and lower side. The upper side of the intermediate layer faces the respective power component, and the lower side of the intermediate layer faces the substrate. Furthermore, the sintered joining region may take up the largest region of the intermediate layer, so the respective solder region is comparatively small.

The respective connection point is used, for example, as the control connection of the respective power component. The respective power component may also have a further connection point that faces the joining region produced by sintering and may be used as the load connection of the respective power component. In principle a plurality of further such connection points may be used, that may be respectively used as the load connection of the respective power component.

The embodiment of the intermediate layer includes a plurality of advantages. By way of example, the respective power component is connected to the substrate for the most part by the sintered joining region of the intermediate layer. The sintered joining region creates, for example, an especially long-lasting, reliable, and robust mechanical connection of the respective power component to the substrate, that also withstands the high thermomechanical stress to which the intermediate layer is subject during the life of the power module. By contrast, the respective connection point, at which the thermomechanical the stress is much lower, is produced with less expensive solder preforms, so a cost advantage compared to a fully sintered intermediate layer is achieved in the power modules.

It is advantageous that the intermediate layer or the connection of the respective power component to the substrate via the illustrated intermediate layer may be produced especially inexpensively and easily. This is due, inter alia, to the fact that design of the sintered joining region and of the respective solder region of the intermediate layer occurs, for example, in one work step. This is possible, for example, in that the solder preform may be fused during the work step of sintering of the joining region produced by sintering or the sintering material may be sintered during the work step of soldering of the solder region. As a result of this both the sintered joining region and the respective solder region are formed during this work step. Furthermore, it is advantageous that the sintering material, from which the sintered joining region is formed, may be compressed to only a limited extent, preventing an inadmissible displacement of the solder during fusing of the solder preform during this work step.

In an embodiment, the joining region produced by sintering is produced by a sinter preform.

A sinter preform is, for example, a sinter preform or a sinter molded part, for example a cuboid, cylinder, ring or the like, made from material to be sintered. Sinter preforms may also be supplied in established dimensions, for example on belts or in trays, and may be processed analogously to SMD (“Surface Mount Devices”) resistors or capacitors.

The use of a sinter preform together with a respective solder preform provides for the respective power component to be connected the substrate easily. For example, the combination of a sinter preform with a respective solder preform means large, sintered regions and small, soldered regions of the intermediate layer may be connected in one sintering or work step, for example also without an additional activation of the solder. A sinter preform may be used for the active, large surface here, and this is decisive for the final thickness of the intermediate layer. For the small, soldered surface, for example at the gate of a power component configured as a transistor, a solder preform may be used that also fuses during the sintering process. Thanks to the sinter preform that may be compressed to only a limited extent, an inadmissible displacement of the solder may be prevented during the sintering process during fusing at the small surface.

The large active surface, that is subject to high thermomechanical stress in the life tests, may thus be connected to the substrate by the sintered joining region, that guarantees a long-lasting, reliable, and robust mechanical connection of the respective power component. The thermomechanical stress is conventionally much lower at the respective connection point, for example the gate of a transistor illustrated above, for which reason a solder preform may be used there in the intermediate layer for producing the connection of the respective power component to the substrate. As already mentioned, such solder preforms are also comparatively inexpensive to obtain.

In an embodiment, the joining region produced by sintering is formed by 3D printing, by a coating method or by screen/stencil printing.

As an alternative to the use of a sinter preform the material to be sintered of the intermediate layer may also be formed by 3D printing, by a coating method or by screen/stencil printing or be attached to or arranged on the substrate. The alternative methods may have the advantage that, compared to the use of a sinter preform, especially delicate or also complicated geometries of the sintered joining region may be achieved. By way of example, by such alternative methods, power modules with complex power components having a large number of connection points or power modules with a large number of (such) power components may be achieved.

One or more sinter preform(s) as well as one or more of the alternative method(s) are used to produce one or more sintered joining region(s) for a power module.

In an embodiment, the respective solder region or the respective solder preform is flux agent-free.

In this case a flux agent is a substance added during soldering, that brings about improved wetting of the workpiece by the solder. It removes the oxides lying on the surfaces by way of a chemical reaction, for example by reduction. The same applies to oxides that are produced during the soldering process due to the oxygen in the air. Flux agents also lower the boundary surface tensions. Depending on the specific requirements or circumstances, flux agents may be acidic or solvent-containing or have an activator, such as zinc chloride, ammonium chloride or organic salts.

Flux agent-free means, for example, that the solder of the solder preform includes no, or virtually no, flux agent. By way of example, the solder of the solder preform is flux agent-free if it includes only, or virtually only, a mixture or an alloy of different metals. It is assumed in this connection that a solder includes “virtually” no flux agent if the amount of flux agent contained in the solder develops at most only negligible effects in respect of wetting of the workpieces, removal of the oxides on the workpieces to be soldered and/or lowering of the boundary surface tensions. For example, it is assumed that a solder includes “virtually” no flux agent if the solder includes only insignificant or undesirable contaminations of flux agent.

Although flux agents are often used in soldering, the formation of the respective solder layer and the connection of the respective power component to the substrate takes place by the flux agent-free solder preform or solder region since with the power module the respective power component is secured to the substrate by way of the joining region, produced by sintering, of the intermediate layer by sintering. Accordingly, both the respective power component and the substrate include at the respective surface facing the other workpiece or contact surface on the intermediate layer, a noble metal surface, for example gold or silver. Since the noble metal surfaces do not, or practically do not, oxidize, the flux agent that is normally necessary for soldering is not necessary.

In an embodiment, the joining region produced by sintering and the respective solder region are arranged side by side between the substrate and the respective power component and have substantially the same layer thickness.

Conventionally the intermediate layer includes a flat configuration, with the respective power component being arranged on its flat upper side and the substrate being arranged on its flat lower side. The sintered joining region and the respective solder region are arranged, for example side by side, inside the intermediate layer in such a way that the sintered joining region or the solder region extends continuously from the flat upper side of the intermediate layer to the opposing, flat lower side intermediate layer. Furthermore, the sintered joining region may take up the largest region of the intermediate layer, so the respective solder region is comparatively small.

The layer thickness of the sintered joining region substantially corresponds to the respective layer thickness of the respective solder region, so the intermediate layer includes a substantially constant layer thickness. Smaller deviations may be tolerable, for example as long as no, or only negligible, cavities or air pockets form inside the sintered joining region and/or the respective solder region, for example as a result of the fact that sintered joining region or the respective solder region does not have a constant layer thickness. Furthermore, smaller deviations may still be tolerable provided only negligible caring exists.

By way of example, the intermediate layer or the sintered joining region and the respective solder region may have a thickness of 10 μm to 300 μm, for example 50 μm to 150 μm or of 90 μm to 110 μm, for example approximately 100 μm. Depending on the embodiment of the power module, tolerances of the layer thickness of the intermediate layer or of the sintered joining region and/or of the respective solder region of ±20%, for example ±10% or only ±5% may still be acceptable.

The layer thicknesses mentioned in conjunction with this embodiment refer, for example, to the completed power module, for example the status after connecting of the respective power component to the substrate by heating the intermediate layer.

In an embodiment, the respective solder region includes a cross-section of at most approx. 9 mm₂, for example of at most approx. 4 mm₂.

The respective solder region may have-in a plane parallel to the flat upper side of the substrate-a round or circular or even a rectangular or square cross-section. With square cross-sections the dimensions may be, for example, 3 mm×3 mm or 2 mm×2 mm. Smaller dimensions, such as 1.6 mm×1.6 mm or even below 2 mm² or 1 mm², such as 0.5 mm×1 mm, may be used. The disclosed cross-sections may match, for example, the cross-sectional area of the respective solder region after the connection of the respective power component to the substrate includes been established.

In an embodiment, the substrate includes a Direct Bonded Copper (DCB) substrate, an Insulated Metal Substrate (IMS), an Active Metal Brazing (AMB) substrate or a printed circuit board. The substrate includes a noble metal surface at its side facing the intermediate layer.

The DCB substrate and the IMS are, for example, carrier structures to which electrical conductor tracks and for example, one or more semiconductor chip(s), power component(s) or other components are or may be applied.

The noble metal surface may have, for example, gold or silver, with the substrate being coated accordingly, for example.

The device including at least one such power module may be configured, for example, as a rectifier, a power inverter or, as an inverter or power converter, or include one of these. For example, the power module or a corresponding device may be used in industrial applications, electrically or hybrid-driven vehicles, such as in trains, cars, ships, boats, or aircraft.

The individual components of the power module may be provided and appropriately arranged according to the method. The intermediate layer may be heated to or slightly above the melting temperature of the solder or to or slightly above the sintering temperature in order to produce the power module. For example, the entire arrangement is heated to or slightly above the corresponding temperature for this purpose. Furthermore, pressure may be exerted on the intermediate layer or the entire arrangement, for example depending on sintering material. By way of example, the sintering material and the respective solder preform may be arranged on the substrate in such a way that, before heating, cavities still remain on the substrate between the sintering material and the respective solder preform.

In an embodiment, the intermediate layer is heated to the melting temperature of the solder if the melting temperature of the solder is higher than the sintering temperature or is heated to the sintering temperature if the sintering temperature is higher than the melting temperature of the solder.

Two variants, that are described below, may be used in this connection.

According to a first variant, first soldering and then sintering may take place. For example a low-melting solder may be used for this purpose, that includes a melting temperature that is lower than the sintering temperature. During the production process of the power module the intermediate layer or arrangement is first heated to the melting temperature of the solder, whereby the solder joint forms. The intermediate layer or arrangement is then heated by way of a further temperature increase to the sintering temperature and optionally pressure is exerted on the intermediate layer or arrangement, whereby the sintered joint is created. The solder may remain molten in the process. The creation of the sintered joint may be carried out in one process step together with the creation of the solder joint, or in a process step separate from this.

According to a second variant, first sintering and then soldering may take place. For example, a high-melting solder may be used for this purpose, that includes a melting temperature that is higher than the sintering temperature. During the production process of the power module the intermediate layer or arrangement is first heated to the sintering temperature and optionally pressure is exerted on the intermediate layer or arrangement, whereby the sintered joint is created. The intermediate layer or arrangement is then heated to the melting temperature of the solder by a further temperature increase, whereby the solder joint is created. Since, during fusing, the solder tends to form spheres due to the surface tension, for example cavities, that could still be present after sintering, may be bridged with this variant. The creation of the solder joint may be carried out in one process step together with the creation of the sintered joint, or in a process step separate from this.

In an embodiment, the layer thickness of the sintering material for the joining region produced by sintering is greater or smaller than the layer thickness of the solder for the respective solder region if the sintering temperature is lower or higher than the melting temperature of the solder.

According to the first variant, in which first soldering and then sintering may take place, the layer thickness of the sintering material is thus less than the layer thickness of the solder. And according to the second variant, in which first sintering and then soldering may take place, the layer thickness of the sintering material is thus greater than the layer thickness of the solder. Since, during fusing, the solder tends to form spheres due to the surface tension, for example cavities, that may still be present after sintering, may be bridged with this variant. The layer thicknesses of the sintering material or of the solder refer to the status of the arrangement before the two connections are created by heating and optionally exerting pressure.

The thicker layer may be 10% to 40% thicker than the thinner layer, for example 15% to 25%. In some examples the thicker layer is approx. 10 μm to 40 μm thicker than the thinner layer, for example 15 μm to 25 μm.

In an embodiment, the melting temperature of the solder is substantially equal to the sintering temperature.

Soldering and sintering may take place practically simultaneously. For this purpose, a solder and a sintering material may be used, with the melting temperature of the solder substantially matching the sintering temperature. Those temperatures which differ from each other by less than 10 K, for example less than 5 K, are regarded as substantially identical temperatures. The sintering temperature may depend on the exertion of pressure on the intermediate layer or arrangement. For example, the temperatures may be very similar in the case of sintering and soldering processes, depending on soldering and sintering methods, for example approx. 240° For fusing of the solder and for sintering. Heating of the intermediate layer or the arrangement for the purpose of sintering is thus sufficient to guarantee fusing of the solder and a reliable formation of the soldering point. For example, the sintering process does not have to be specially adapted therefore. The solder joint and the sintered joint may be produced especially easily in one work step.

In some examples the layer thickness of the solder preform may be selected to be slightly thicker than the layer thickness of the sintering material, for example thicker by 5% to 15% or approx. 5 μm to 15 μm. The slice thicknesses of the sintering material or of the solder refer to the status of the arrangement before the two connections are created by heating and optionally exerting pressure.

In an embodiment, the layer thickness of the sintering material for the joining region produced by sintering is substantially identical to the layer thickness of the solder for the respective solder region.

The thickness of the solder preform may substantially match the thickness of the sintering materials before the two connections are created by heating and exerting pressure. For example, the thickness of the solder preform is down to less than ±10 μm or ±10%, for example less than ±5 μm or +5%, equal to the thickness of the sintering materials. The slice thicknesses of the sintering material or of the solder refer to the status of the arrangement before the two connections are created by heating and exerting pressure.

The method for producing the power module may include, for example, the method steps in conjunction with the power module. This relates, for example, to the method steps for producing the intermediate layer or the respective solder region and the joining region produced by sintering.

### BRIEF DESCRIPTION OF THE FIGURES

FIGS. 1-2 depict a first and a second embodiment of a power module.

FIGS. 3-6 depict flowcharts of a first to fourth embodiment of the method.

FIG. 7 depicts a first intermediate result in the production of an embodiment of the power module.

FIGS. 8-9 depict a first and a second intermediate result in the production of a fourth embodiment of the power module.

FIGS. 10-11 depict cross-sections through a fifth embodiment of the power module.

FIG. 12 depicts an embodiment of an electrical device.

### DETAILED DESCRIPTION

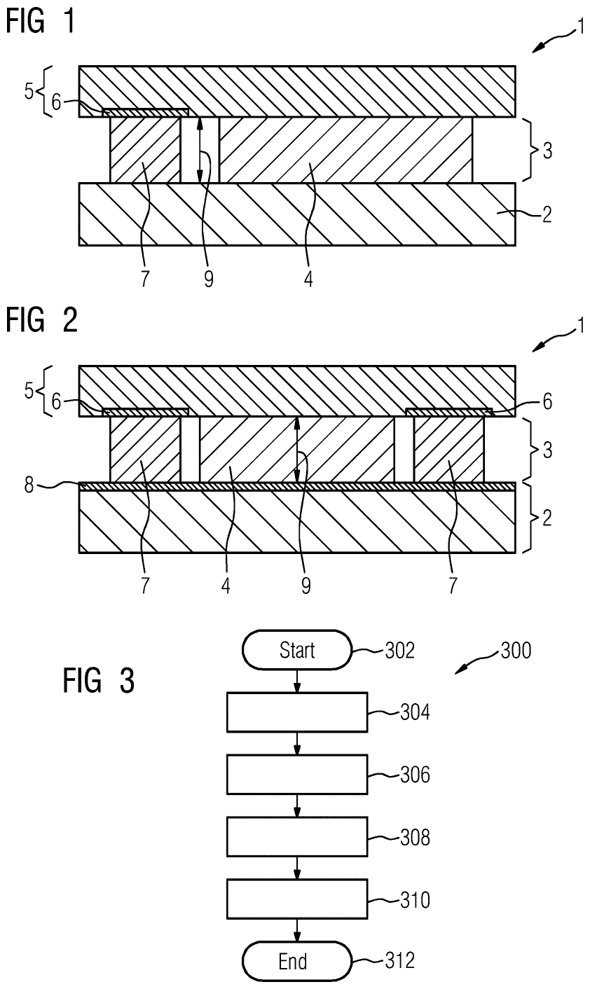

FIG. 1 depicts a first embodiment of the power module 1, with a cross-section through the power module 1 being represented.

The power module 1 includes a substrate 2 on which an electrically conductive intermediate layer 3 is arranged. The intermediate layer 3 includes a joining region 4 produced by sintering. Furthermore, the power module 1 includes a power component 5, that is arranged on the intermediate layer 3 and that includes one or more connection point(s) 6 connected to the intermediate layer 3. Furthermore, the intermediate layer 3, in the region of the connection point 6, includes a solder region 7, that is connected to the connection point 6 and that is produced by a solder preform.

The connection point 6 may be used, for example, as a control connection of the power component 5. Furthermore, the power component 5 may also have a further connection point, that faces the joining region 4 produced by sintering and may be used as the load connection of the power component 5. In principle a plurality of such further connection points is also conceivable, that may be used as a load connection of the respective power component 5 respectively.

Connection structures for making contact with the intermediate layer 3 may already be present in the case of both the power component 5 and the substrate 2. The substrate 2, for example, may thus have a structured configuration, with the structures not being shown in FIG. 1. The structuring may be achieved, for example, in that the substrate 2 includes an electrically conductive surface, that faces the intermediate layer 3, with this surface having electrically non-conductive recesses or gaps, whereby two or more regions of this surface are electrically insulated from each other. For example, an electrical insulation of the solder region 7 from the joining region 4 produced by sintering may also be created thereby. By way of example, the substrate 2 may also be configured with multiple layers.

The sintered joining region 4 may be produced, for example, by a sinter preform. Alternatively or in addition, the sintered joining region 4 may be embodied by 3D printing, by a coating method or by screen/stencil printing.

For example, the respective solder region 7 or the respective solder preform may be flux agent-free.

As represented in FIG. 1, the sintered joining region 4 and the solder region 7 may be arranged side by side between the substrate 2 and the power component 5 and have substantially the same layer thickness 9.

The respective solder region 7 may include a cross-section of at most approx. 9 mm², for example of at most 4 mm², with a plane parallel to the flat upper side of the substrate 2 being considered.

By way of example, the substrate 2 may include a Direct Bonded Copper (DCB) substrate, an Insulated Metal Substrate (IMS), an Active Metal Brazing (AMB) substrate or a printed circuit board.

FIG. 2 depicts a second embodiment of the power module 1, with a cross-section through the power module 1 again being represented. Identical reference numerals to those in FIG. 1 denote identical items.

The substrate 2 includes, at its side facing the intermediate layer 3, a noble metal surface 8, for example having gold or silver. The substrate 2 includes a Direct Bonded Copper (DCB) substrate, an Insulated Metal Substrate (IMS), an Active Metal Brazing (AMB) substrate or a printed circuit board.

There may already be connection structures for making contact with the intermediate layer 3 present in the case of both the power component 5 and the substrate 2, for example, in respect of the noble metal surface 8. For example, the noble metal surface 8 may thus have a structured configuration, with the structures not being shown in FIG. 2. The structuring may be achieved, for example, in that the noble metal surface 8 forms an electrically conductive surface, with this surface having electrically non-conductive recesses or gaps, whereby two or more regions of this surface are electrically insulated from each other. For example, an electrical insulation of the solder region 7 from the joining region 4 produced by sintering may also be created thereby. By way of example, the substrate 2 may also have a multi-layer configuration.

Furthermore, the power module 1 includes two connection points 6 and the intermediate layer includes two solder regions 7. The respective solder region 7 is arranged in the region of the respective connection point 6 and is connected to the respective connection point 6. The respective solder region 7 is produced by a solder preform.

The two connection points 6 are used, for example, as control connections of the power component 5. The power component 5 may also have one or more further connection point(s), that face(s) the joining region 4 produced by sintering and may be used as a load connection or as load connections of the power component 5.

FIG. 3 depicts a flowchart 300 of a first embodiment of the method. The sequence starts with step 302 and includes at least the following steps. The substrate is provided in step 304. The sintering material for the sintered joining region and the solder for the respective solder region are provided on the substrate in step 306 for forming the intermediate layer, with the solder being provided for the respective solder region in the region of the respective connection point of the respective power component and as a solder preform. The respective power component is arranged on the joining region produced by sintering and the respective solder region on the intermediate layer in step 308. The intermediate layer is heated to the melting temperature of the solder or to the sintering temperature in step 310. The sequence ends with step 312.

In advantageous embodiments of the method the flowchart may also include even further steps, that are explained further above and below.

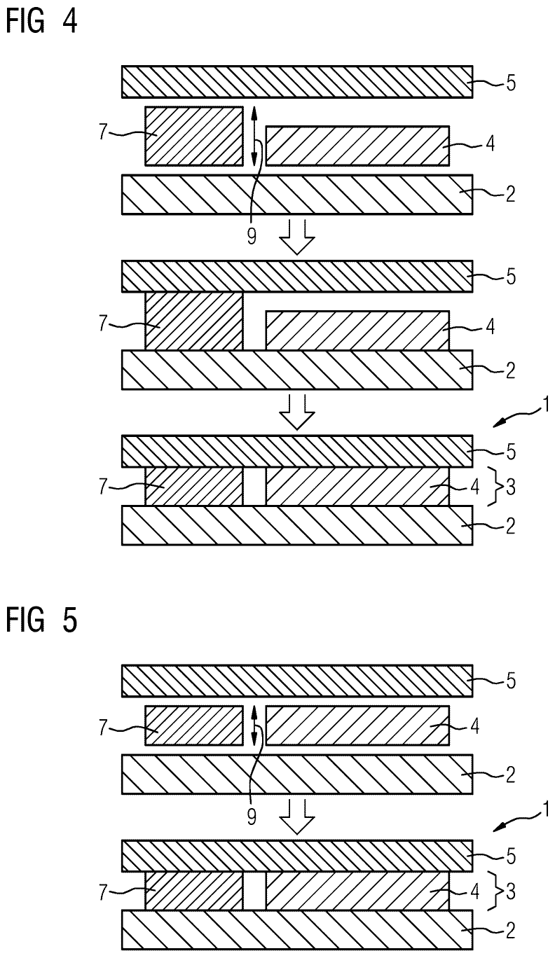

FIG. 4 depicts a flowchart of a second embodiment of the method. The substrate 2, the sintering material for the sintered joining region 4, the solder preform for the solder region 7 and the power component 5 are provided and appropriately arranged. The respective connection point 6 is not shown in FIG. 4 solely for reasons of clarity.

In this embodiment, first soldering and then sintering take place. A low-melting solder, for example, may be used for this purpose, that includes a melting temperature that is lower than the sintering temperature. During the production process of the power module 1 the intermediate layer 3 or arrangement is first heated to the melting temperature of the solder, whereby the solder joint is created. The solder remains molten. The intermediate layer 3 or arrangement is then heated to the sintering temperature by way of a further temperature increase and optionally pressure is exerted on the intermediate layer 3 or arrangement, whereby the sintered joint is created. The creation of the sintered joint may be carried out in one process step together with the creation of the solder joint or in process steps separate from this.

The solder preform may be thicker by 10% to 40% than the sintering material, for example 15% to 25%. In some examples the solder preform is approx. 10 μm to 40 μm thicker than the sintering material, for example 15 μm to 25 μm. The layer thicknesses of the sintering material or of the solder refer to the status of the arrangement before the two connections are created by heating and optionally exerting pressure.

FIG. 5 depicts a flowchart of a third embodiment of the method. The substrate 2, the sintering material for the joining region 4, the solder preform for the solder region 7 and the power component 5 are again produced and appropriately arranged. The respective connection point 6 is now shown in FIG. 5, likewise solely for reasons of clarity.

According to this embodiment, soldering and sintering take place practically simultaneously. A solder and a sintering material may be used for this, with the melting temperature of the solder substantially matching the sintering temperature. For example, the temperatures may be very similar in the sintering and soldering processes, depending on the soldering and sintering methods, for example approx. 240° For fusing the solder and for sintering. Heating of the intermediate layer 3 or the arrangement for the purpose of the sintering is thus sufficient to guarantee fusing of the solder and a reliable formation of the soldering point. For example, the sintering process does not need to be specially adapted, therefore. It is advantageous in this variant that the solder joint and the sintered joint may be produced in one work step.

The thickness of the solder preform may substantially match the thickness of the sintering material before the two connections are created by heating and optionally exerting pressure. For example, the thickness of the solder preform is down to less than ±10 μm or ±10%, for example less than ±5 μm or ±5%, equal to the thickness of the sintering material.

In some examples the layer thickness 9 of the solder preform may be selected to be slightly thicker than the layer thickness 9 of the sintering material, for example for example thicker by 5%to 15%or approx. 5 um to 15 um. The layer thicknesses of the sintering material or of the solder refer to the status of the arrangement before the two connections are created by heating and optionally exerting pressure.

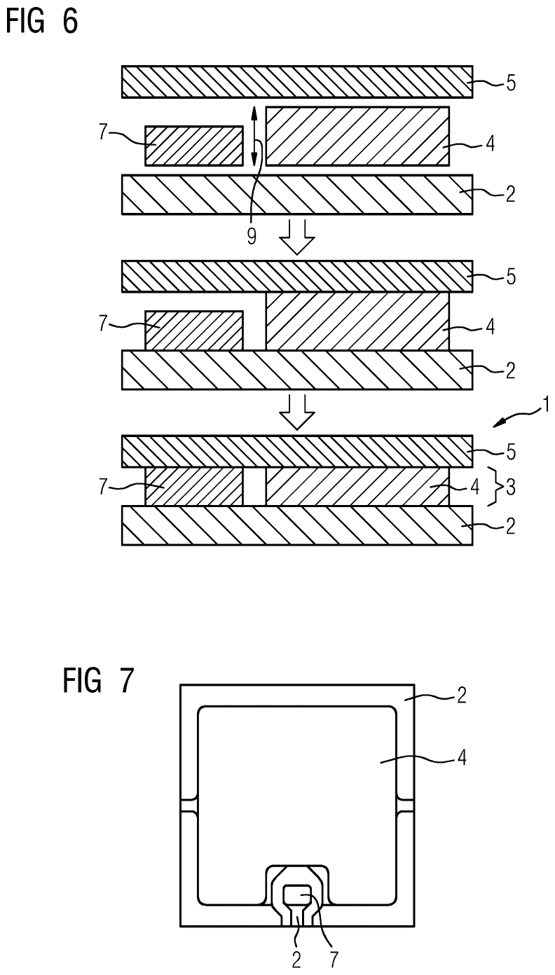

FIG. 6 depicts a flowchart of a fourth embodiment of the method. The substrate 2, the sintering material for the joining region 4, the solder preform for the solder region 7 and the power component 5 are again provided and appropriately arranged. The respective connection point 6 is not shown in FIG. 6, again solely for reasons of clarity.

According to this embodiment, first sintering and then soldering take place. For example, a high-melting solder may be used for this, that includes a melting temperature that is higher than the sintering temperature. During the production process of the power module 1 the intermediate layer 3 or arrangement is first heated to the sintering temperature and optionally pressure is exerted on the intermediate layer or arrangement, whereby the sintered joint is created. The intermediate layer 3 or the arrangement is then heated to the melting temperature of the solder by way of a further temperature increase, whereby the solder joint is created. The creation of the solder joint may be carried out in one process step together with the creation of the sintered joint or in process steps separate from this.

The sintering material may be thicker by 10%to 40%than the solder preform, for example 15% to 25%. In some examples the sintering material is approx. 10 μm to 40 um thicker than the solder preform, for example 15 μm to 25 μm. The layer thicknesses of the sintering material or of the solder refer to the status of the arrangement before the two connections are created by heating and optionally exerting pressure.

FIG. 7 depicts a first intermediate result in the production of a third embodiment of the power module 1. A plan view of the substrate 2 is represented, to which a sinter paste is applied in this third embodiment for the joining region 4. A solder preform for the solder region 7 is also applied to the substrate 2, with the solder region 7 being arranged spaced apart from the joining region 4.

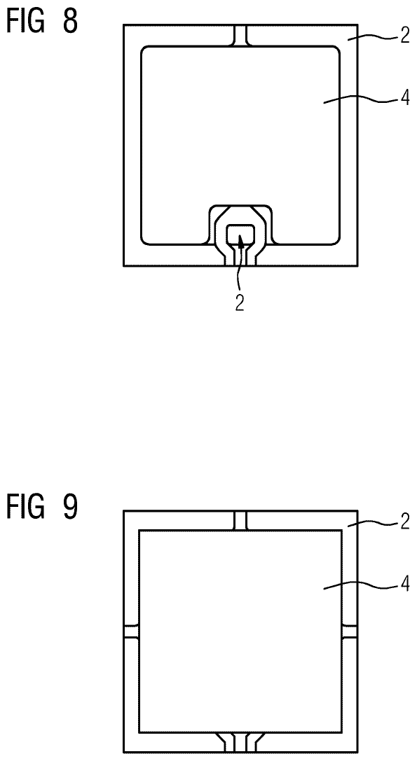

FIGS. 8 and 9 depict a first and a second intermediate result in the production of a fourth embodiment of the power module 1. As in the third embodiment represented in FIG. 7, a plan view of the substrate 2 is again represented. As represented in FIG. 8, a sinter preform for the sintered joining region 4 a solder preform for the solder region 7 are applied to the substrate 2, with the solder region 7 again being arranged spaced apart from the sintered joining region 4. As represented in FIG. 9, the power component 5 is connected to the sintered joining region 4 and the solder region 7 and henceforth covers it in the represented plan view.

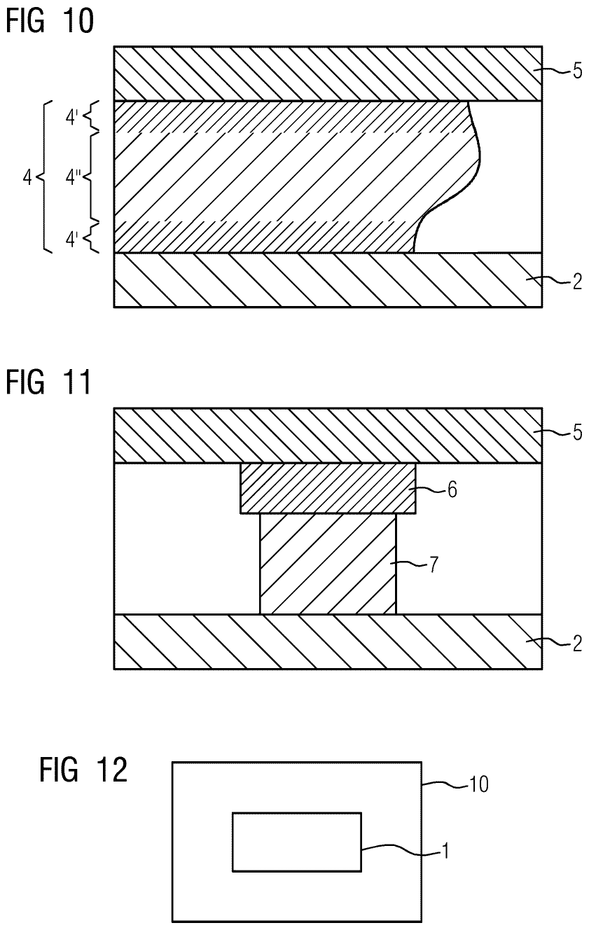

FIGS. 10 and 11 show cross-sections through a fifth embodiment of the power module 1.

FIG. 10 depicts the cross-section through the sintered joining region 4 of the power module 1. For this sintered joining region 4 a sinter preform was used that, after sintering, includes a hard sintering core 4″. The sintered joining region 4 also includes two edge regions 4′, formed partially during sintering, of which one is arranged between the sintering core 4″ and the substrate 2 and the other between the sintering core 4″ and the power component 5. By way of example, the sintered joining region 4 may have a sintering core 4″ configured as a solid material, that on both sides, for example facing the power component 5 and facing the substrate 2, includes one sintering material respectively. In addition, a layered, sintered joining region 4 would also be conceivable in which sintering material and solid material alternate in layers, for example sintering material-solid material-sintering material-solid material-sintering material.

FIG. 11 depicts the cross-section through the solder region 7 of the power module 1. A solder preform was used for this solder region 7. Furthermore, a connection point 6 is represented, that is arranged between the remainder of the power component 5 and the solder region 7. The solder region 7 is arranged between the connection point 6 and the substrate 7.

FIG. 12 depicts an embodiment of the electrical device 10. The electrical device 10 includes the power module 1. By way of example, the electrical device 10 is configured as an inverter.

It is to be understood that the elements and features recited in the appended claims may be combined in different ways to produce new claims that likewise fall within the scope of the present embodiments. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present embodiments have been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A power module comprising
a substrate,
an electrically conductive intermediate layer which that is arranged on the substrate and includes a joining region produced by sintering; and
at least one power component that is arranged on an intermediate layer respectively and which has at least one connection point connected to the intermediate layer respectively;
wherein the intermediate layer includes, in a region of the respective connection point of the at least one connection point, a solder region produced by means of a solder preform, which that is connected to the respective connection point.

2. The power module of claim 1, wherein the joining region produced by sintering is produced by a sinter preform.

3. The power module of claim 1, wherein the joining region produced of sintering is generated using 3D printing by a coating method or by screen/stencil printing.

4. The power module of claim 1, wherein the respective solder region or the respective solder preform is flux agent-free.

5. The power module of claim 1, wherein the joining region produced by means of sintering and the respective solder region are arranged side by side between the substrate and the respective power component and have substantially a same layer thickness.

6. The power module of claim 1, wherein the respective solder region includes a cross-section of at most 9 mm².

7. The power module of claim 1, wherein the substrate comprises a Direct Bonded Copper (DCB) substrate, an Insulated Metal Substrate (IMS), an Active Metal Brazing (AMB) substrate or a printed circuit board, and wherein the substrate includes, at a side facing the intermediate layer, a noble metal surface.

8. (canceled)

9. A method for producing a power module, the method comprising the method steps:
providing a substrate;
arranging sinter material for a joining region to be sintered and solder for a respective solder region on the substrate to form an intermediate layer, wherein the solder for the respective solder region is provided as a solder preform in a region of a respective connection point the a respective power component;
arranging the respective power component on the joining region and the respective solder region or on the intermediate layer; and
heating the intermediate layer to a melting temperature of the solder or to a sintering temperature.

10. The method of claim 9, wherein the intermediate layer is heated to the melting temperature of the solder when the melting temperature of the solder is higher than the sintering temperature, or is heated to the sintering temperature when the sintering temperature is higher than the melting temperature of the solder.

11. The method of claim 9, wherein a layer thickness of the sintering material for the joining region produced by means of sintering is greater or less than layer thickness of the solder for the respective solder region when the sintering temperature is less or greater than the melting temperature of the solder.

12. The method of claim 9, wherein the melting temperature of the solder is substantially equal to the sintering temperature.

13. The method of claim 9, wherein a layer thickness of the sintering material for the joining region produced by means of sintering is substantially equal to a layer thickness of the solder for the respective solder region.

14. An electrical device comprising:
at least one power module comprising:
a substrate;
an electrically conductive intermediate layer that is arranged on the substrate and includes a joining region produced by sintering; and
at least one power component that is arranged on an intermediate layer respectively and which has at least one connection point connected to the intermediate layer respectively;
wherein the intermediate layer includes, in a region of the respective connection point of the at least one connection point, a solder region produced by a solder preform, that is connected to the respective connection point.

15. The electrical device of claim 14, wherein the joining region produced by sintering is produced by a sinter preform.

16. The electrical device of claim 14, wherein the joining region produced of sintering is generated using 3D printing by a coating method or by screen/stencil printing.

17. The electrical device of claim 14, wherein the respective solder region or the respective solder preform is flux agent-free.

18. The electrical device of claim 14, wherein the joining region produced by sintering and the respective solder region are arranged side by side between the substrate and the respective power component and have substantially a same layer thickness.

19. The electrical device of claim 14, wherein the respective solder region includes a cross-section of at most 9 mm2.

20. The electrical device of claim 14, wherein the substrate comprises a Direct Bonded Copper (DCB) substrate, an Insulated Metal Substrate (IMS), an Active Metal Brazing (AMB) substrate or a printed circuit board, and wherein the substrate includes, at a side facing the intermediate layer, a noble metal surface.
